(19) United States
(12) Patent Application Publication
(10) Pub. No.: US 2009/0165950 A1
(43) Pub. Date: Jul. 2, 2009

(54) Apparatus for treating substrate and method for transferring substrate using the same

(76) Inventors: Duk-Sik Kim, Chungcheongnam-do (KR); Joon-Jae Lee, Chungcheongnam-do (KR)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/290,966

(22) Filed: Nov. 4, 2008

(30) Foreign Application Priority Data
Dec. 27, 2007 (KR) 2007-138757

(51) Int. Cl. H01L 21/306; B65H 1/00

(52) U.S. Cl. 156/345.1; 414/806

(57) ABSTRACT

A substrate treating apparatus and a method for transferring a substrate are provided. The substrate treating apparatus includes a first treating unit having a dual layer structure in which a first treating portion performing a coating process and a second treating portion performing a developing process are arranged in a vertical direction, a first buffer unit providing a place where substrates treated at the first treating portion stand by, a second buffer unit providing a place where the substrates treated at the second treating portion stand by, a second treating unit performing an exposing process, and an interface unit transferring the substrates between the first and second buffer units and the second treating unit. The interface unit includes a frame disposed adjacent to the first treating unit and a first substrate receiving portion disposed in the frame and receiving the substrates that are received in the first buffer unit and will be transferred to the second treating unit.

### CROSS-REFERENCE TO RELATED APPLICATION

This U.S. non-provisional patent application claims priority under 35 U.S.C. § 119 of Korean Patent Application No. 10-2007-0138757, filed on Dec. 27, 2007, the entire contents of which are hereby incorporated by reference.

### BACKGROUND OF THE INVENTION

The present invention disclosed herein relates to a substrate treating apparatus and a method for transferring a substrate using the same, and more particularly, to an in-line type substrate treating apparatus having an interface unit for transferring a substrate between a treatment unit performing coating and developing processes and an exposure unit performing an exposing process and a method for transferring a substrate using the same.

Semiconductor devices are manufactured by repeatedly performing a process of sequentially stacking thin films on a silicon wafer to form a predetermined circuit pattern. In order to form and stack the thin films, a plurality of unit processes such as a deposition process, a photolithography process, and an etching process must be repeatedly performed.

The photography process is for forming a pattern on a wafer. The photography process includes a coating process, an exposing process, a wide expose edge (WEE) process, and a developing process. The developing process is for making the semiconductor device correspond to a predetermined pattern on the wafer by etching an uppermost layer of the wafer using the pattern.

The coating process is for uniformly applying photo-resist (PR) that is light-sensitive on a surface of the wafer using a coater. The exposing process is for exposing the circuit pattern on the wafer, on which the photo-resist is formed, by allowing light to pass through the circuit pattern of a mask using a stepper. The WEE process is for exposing unnecessary photo-resist applied to an edge of the wafer using a peripheral exposing unit. The developing process is for developing a portion of the wafer, which is exposed through the exposing process, using a developer.

When the above-described processes are individually performed by separate units, the part's movement length increases and thus the transfers between the works are time-consuming. In addition, since the wafer is exposed to the air for a long time, the wafer may be easily contaminated. In order to solve these limitations, an in-line type substrate treating apparatus in which the coater, developer, baking unit, peripheral exposing unit, and stepper are sequentially disposed in a predetermined arrangement has been developed.

The in-line type substrate treating apparatus for performing the photolithography process includes a spinner device for performing the coating and developing processes and a scanner device for performing the exposing process transferring the pattern on the wafer that has gone through the coasting process. The wafer is transferred between the spinner and scanner devices by an interface unit between the spinner and scanner devices.

### SUMMARY OF THE INVENTION

The present invention provides a substrate treating apparatus and a method for transferring a substrate, which can more effectively transfer the substrate between a spinner device and a scanner device.

Other features will be apparent to those skilled in the art from the description and drawings, and from the claims.

Embodiments of the present invention provide substrate treating apparatuses including: a first treating unit having a dual layer structure in which a first treating portion performing a coating process and a second treating portion performing a developing process are arranged in a vertical direction; a first buffer unit providing a place where substrates treated at the first treating portion stand by; a second buffer unit providing a place where the substrates treated at the second treating portion stand by; a second treating unit performing an exposing process; and an interface unit transferring the substrates between the first and second buffer units and the second treating unit, wherein the interface unit includes: a frame disposed adjacent to the first treating unit; and a first substrate receiving portion disposed in the frame and receiving the substrates that are received in the first buffer unit and will be transferred to the second treating unit.

In some embodiments, the first buffer unit may be provided at a first side of the first substrate receiving portion in the frame such that the first buffer unit is located at a height corresponding to the first treating portion, and the second buffer unit may be provided at a second side of the first substrate receiving portion in the frame such that the second buffer unit is located at a height corresponding to the second treating portion.

In other embodiments, the interface unit may be disposed in the frame and further comprises a second substrate receiving portion for receiving the substrates that are transferred from the second treating unit and exposed.

In still other embodiments, the first and second substrate receiving portions may be arranged in a same order as the first and second treating portions that are arranged in the vertical direction.

In even other embodiments, the first buffer unit may be provided in the frame such that the first buffer unit is disposed at an opposite side of the second substrate receiving portion with reference to the first substrate receiving portion, and the second buffer unit may be provided in the frame such that the first buffer unit is disposed at an opposite side of the first substrate receiving portion with reference to the second substrate receiving portion.

In yet other embodiments, the first buffer unit may be provided in the frame such that the first buffer unit is disposed at an opposite side of the second substrate receiving portion with reference to the first substrate receiving portion, and the second buffer unit may be provided between the first buffer unit and the first substrate receiving portion.

In further embodiments, the first buffer unit may be provided adjacent to the interface unit in the first treating portion, and the second buffer unit is provided in the frame such that the second buffer unit is disposed at an opposite side of the first substrate receiving portion with reference to the second substrate receiving portion.

In even further embodiments, the first buffer unit may be provided in the frame such that the first buffer unit is disposed at an opposite side of the second substrate receiving portion with reference to the first substrate receiving portion, and the second buffer unit may be provided adjacent to the interface unit in the second treating portion.

In even further embodiments, the first buffer unit may be provided adjacent to the interface unit in the first treating portion, and the second buffer unit is provided adjacent to the interface unit in the second treating portion.

In other embodiments of the present invention, substrate treating apparatus include: a first treating unit having a dual layer structure in which a first treating portion performing a coating process and a second treating portion performing a developing process are arranged in a vertical direction; a first buffer unit providing a place where substrates treated at the first treating portion stand by; a second buffer unit providing a place where the substrates treated at the second treating portion stand by; a second treating unit performing an exposing process; an interface unit transferring the substrates between the first and second buffer units and the second treating unit, wherein the interface unit includes: a frame disposed adjacent to the first treating unit; and a second substrate receiving portion disposed in the frame and receiving the substrates that are exposed and transferred from the second treating unit.

In some embodiments, the first buffer unit may be provided at a first side of the second substrate receiving portion in the frame such that the first buffer unit is located at a height corresponding to the first treating portion, and the second buffer unit may be provided at a second side of the second substrate receiving portion in the frame such that the second buffer unit is located at a height corresponding to the second treating portion.

In other embodiments, the first buffer unit may be provided at a first side, which corresponds to a height at which the first treating portion is located, of one upper and lower portions of the second substrate receiving portion in the frame, and the second buffer unit may be provided adjacent to the interface unit in the second treating portion.

In yet further embodiments, methods for transferring between first and second treating units using the substrate treating apparatus of the above-described substrate treating apparatus include transferring the substrates treated in the first treating portion to the first buffer unit; transferring the substrates from the first buffer unit to the first substrate receiving portion; transferring the substrates from the first substrate receiving portion to the second treating unit; transferring the substrates that are exposed at the second treating unit to the second buffer unit; and transferring the substrates from the second buffer unit to the second treating portion.

In some embodiments, the substrates treated at the first treating portion may be transferred to the first substrate receiving portion via the first buffer unit that is provided at a first side of the first substrate receiving portion in the frame such that the first buffer unit is located at a height corresponding to the first treating portion, and the substrates that are exposed at the second treating unit are transferred to the second treating portion via the second buffer unit that is provided at a second side of the first substrate receiving portion in the frame such that the second buffer unit may be located at a height corresponding to the second treating portion.

In still other embodiments of the present invention, methods for transferring between first and second treating units using the substrate treating apparatus of the above-described substrate treating apparatus include transferring the substrates treated in the first treating portion to the first buffer unit; transferring the substrates from the first buffer unit to the first substrate receiving portion; transferring the substrates from the first substrate receiving portion to the second treating unit; transferring the substrates that are exposed at the second treating unit to the second substrate receiving portion; transferring the substrates from the second substrate receiving portion to the second buffer unit; and transferring the substrates from the second buffer unit to the second treating portion.

In some embodiments, the first and second substrate receiving portions may be arranged in a same order as the first and second treating portions that are arranged in the vertical direction.

In other embodiments, the substrates treated at the first treating portion may be transferred to the first substrate receiving portion via the first buffer unit that is disposed at an opposite side of the second substrate receiving portion with reference to the first substrate receiving portion, and the substrates that are exposed and receiving in the second substrate receiving portion are transferred to the second treating portion via the second buffer unit that is disposed at an opposite side of the first substrate receiving portion with reference to the second substrate receiving portion.

In still other embodiments, the substrates treated at the first treating portion may be transferred to the first substrate receiving portion via the first buffer unit that is provided in the frame such that the first buffer unit is disposed at an opposite side of the second substrate receiving portion with reference to the first substrate receiving portion, and the substrates that are exposed and receiving in the second substrate receiving portion may be transferred to the second treating portion via the second buffer unit that is provided in the frame such that the second buffer unit is disposed between the first buffer unit and the first substrate receiving portion.

In still further other embodiments, the substrates treated at the first treating portion may be transferred to the first substrate receiving portion via the first buffer unit that is provided adjacent to the interface unit in the first treating portion, and the substrates that are exposed and receiving in the second substrate receiving portion are transferred to the second treating portion via the second buffer unit that is provided in the frame such that the second buffer unit is disposed at an opposite side of the first substrate receiving portion with reference to the second substrate receiving portion.

In still further yet other embodiments, the substrates treated at the first treating portion may be transferred to the first substrate receiving portion via the first buffer unit that is provided in the frame such that the first buffer unit is disposed at an opposite side of the second substrate receiving portion with reference to the first substrate receiving portion, and the substrates that are exposed and receiving in the second substrate receiving portion may be transferred to the second treating portion via the second buffer unit that is provided adjacent to the interface unit in the second treating portion.

In still yet further embodiments, the substrates treated at the first treating portion may be transferred to the first substrate receiving portion via the first buffer unit that is provided adjacent to the interface unit in the first treating portion, and the substrates that are exposed and receiving in the second substrate receiving portion may be transferred to the second treating portion via the second buffer unit that is provided adjacent to the interface unit in the second treating portion.

In even other embodiments of the present invention, methods for transferring between first and second treating units using the substrate treating apparatus of the above-described substrate treating apparatus include: transferring the substrates treated in the first treating portion to the first buffer unit; transferring the substrates from the first buffer unit to the second treating unit; transferring the substrates that are exposed at the second treating unit to the second substrate receiving portion; transferring the substrates from the second substrate receiving portion to the second buffer unit; and transferring the substrates from the second buffer unit to the second treating portion.

In some embodiments, the substrates treated at the first treating portion may be transferred to the second treating unit via the first buffer unit that is provided at a first side of the second substrate receiving portion in the frame such that the first buffer unit is located at a height corresponding to the first treating portion, the substrates that are exposed at the second treating unit may be transferred to the second substrate receiving portion between the first and second buffer units, and the substrates received in the second substrate receiving portion may be transferred to the second treating portion via the second buffer unit that is provided at a second side of the second substrate receiving portion in the frame such that the second buffer unit is located at a height corresponding to the second treating portion.

In other embodiments, the substrates treated at the first treating portion may be transferred to the second treating unit via the first buffer unit that is provided at a first side, which corresponds to a height at which the first treating portion is located, of one of upper and lower portions of the second substrate receiving portion in the frame, the substrates that are exposed at the second treating unit may be transferred to the second substrate receiving portion, and the substrates received in the second substrate receiving portion may be transferred to the second treating portion via the second buffer unit that is provided adjacent to the interface unit in the second treating portion.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a top-plan view of a substrate treating apparatus according to an embodiment of the present invention;

FIG. 2 is a side view of the substrate treating apparatus of FIG. 1;

FIG. 3 is a schematic view of a first treating unit of the substrate treating apparatus of FIG. 1;

FIG. 4 is a schematic view illustrating a substrate transferring path in the substrate treating apparatus of FIG. 2;

FIG. 5 is a side view of a substrate treating apparatus according to a second embodiment of the present invention;

FIG. 6 is a schematic view illustrating a substrate transferring path in the substrate treating apparatus of FIG. 5;

FIG. 7 is a side view of a substrate treating apparatus according to a third embodiment of the present invention;

FIG. 8 is a side view of a substrate treating apparatus according to a fourth embodiment of the present invention;

FIG. 9 is a side view of a substrate treating apparatus according to a fifth embodiment of the present invention;

FIG. 10 is a side view of a substrate treating apparatus according to a sixth embodiment of the present invention;

FIG. 11 is a side view of a substrate treating apparatus according to a seventh embodiment of the present invention;

FIG. 12 is a side view of a substrate treating apparatus according to a eighth embodiment of the present invention;

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Reference numerals are indicated in detail in preferred embodiments of the present invention, and their examples are represented in reference drawings. In every possible case, like reference numerals are used for referring to the same or similar elements in the description and drawings. Accordingly, in some embodiments, well-known processes, well-known device structures, and well-known techniques will not be described in detail to avoid ambiguous interpretation of the present invention. Like reference numerals refer to like elements throughout.

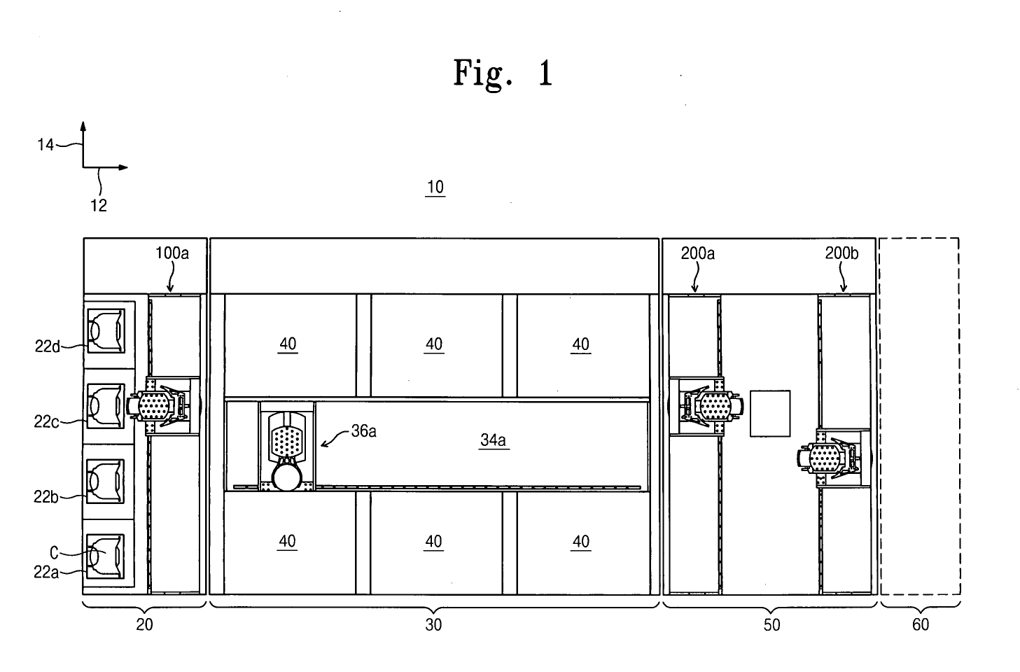

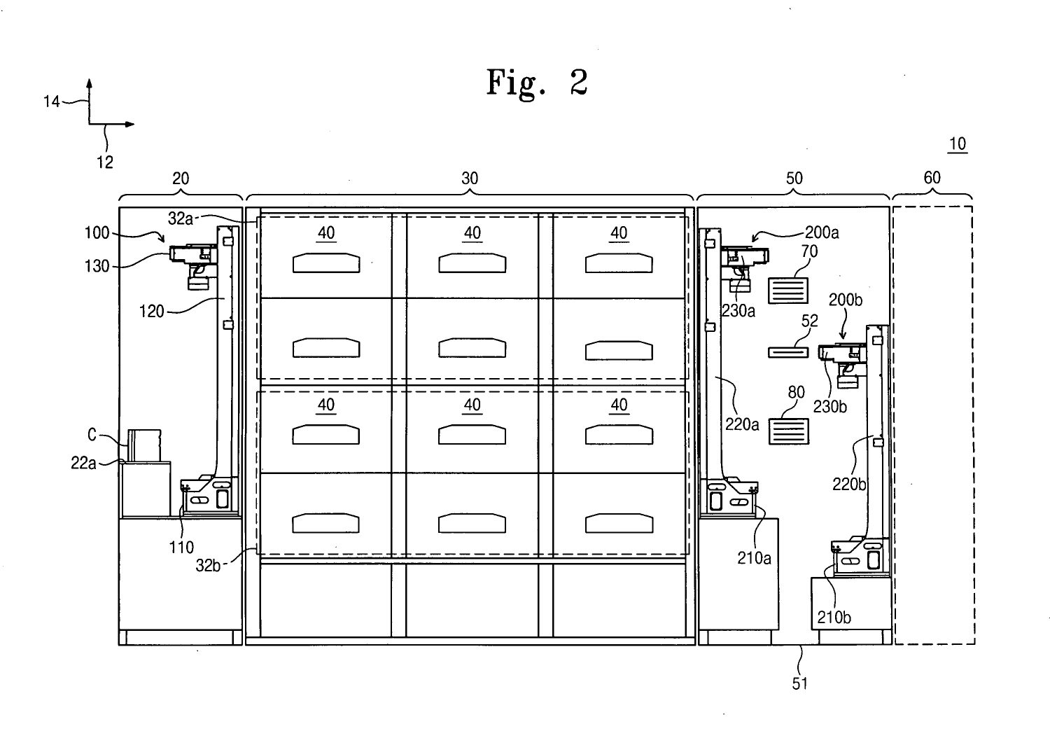

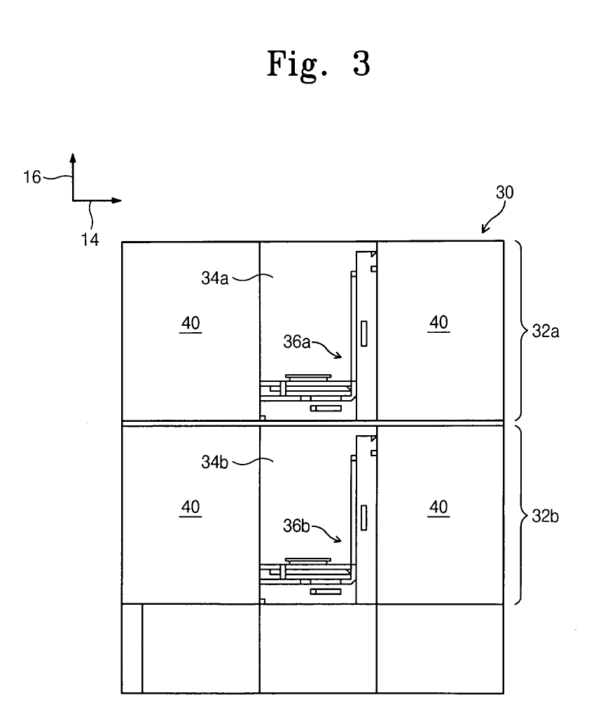

FIG. 1 is a top-plan view of a substrate treating apparatus according to an embodiment of the present invention, FIG. 2 is a side view of the substrate treating apparatus of FIG. 1, and FIG. 3 is a schematic view of a first treating unit of the substrate treating apparatus of FIG. 1.

Referring to FIGS. 1 to 3, a substrate treating apparatus 10 includes an indexer 20, a first treating unit 30, and an interface unit 50. The indexer 20, first treating unit 30, and interface unit 50 are arranged in parallel along a line extending in a first direction 12. The indexer 20 is adjacent to a front end portion of the first treating unit 30 on the line in the first direction 12. The interface unit 50 is adjacent to a rear end portion of the first treatment unit 30 on the line in the first direction 12. Each of the indexer 20 and interface unit 50 has a length extending in a second direction 14 perpendicular to the first direction 12. The first treating unit 30 has a multi-layer structure staked in a vertical direction. The first treating unit 30 includes a first treating portion 32a at an upper layer and a second treating portion 32b at a lower layer. If necessary, a second treating unit (an exposing unit) 60 performing an exposing process may be connected to a rear end of the interface unit 50 on the line extending in the first direction 12.

The indexer 20 is installed on a front end portion of the first treating unit 30. The indexer 20 includes load ports 22a, 22b, 22c, and 22d in which cassettes receiving substrates are disposed and an indexer robot 100. The load ports 22a, 22b, 22c, and 22d are arranged in parallel along a line extending in the second direction 14. The indexer robot 100 is disposed between the first treating unit 30 and the load ports 22a, 22b, 22c, and 22d. A container C receiving the substrates is located on the load ports 22a, 22b, 22c, and 22c by a transferring unit (not shown) such as an overhead transfer, an overhead conveyer, or an automatic guided vehicle. An enclosed container such as a front open unified pod (FOUP) may be used as the container C. The indexer robot 100 transfers the substrate between the container C located on the load ports 22a, 22b, 22c, ad 22d and the first treating unit 30.

The indexer robot 100 includes a horizontal guide 110, a vertical guide 120, and a robot arm 130. The robot arm 130 is linearly movable in the first direction 12 and is rotatable about a Z-axis. The horizontal guide 110 guides linear movement of the robot arm 130 in the second direction 14. The vertical guide 120 guides linear movement of the robot arm 130 in a third direction 16. The robot arm 130 linearly moves in the second direction 14 along the horizontal guide 110. The robot arm 130 is rotatable about the Z-axis and is movable in the third direction 16.

The first treating portion 32a includes a first transfer passage 34a, a first main robot 26a, and treating modules 40. The first transfer passage 34a extends from a location adjacent to the indexer 20 to a location adjacent to the interface unit 50 in the first direction 12. The treating modules 40 are arranged along the length direction of the first transfer passage 34a at both sides of the first transfer passage 34a. The first main robot 36a is installed on the first transfer passage 34a. The first main robot 36a transfers the substrates between the indexer 20, treating modules 40, and interface unit 50.

The second treating portion 32b includes a second transfer passage 34b, a second main robot 36b, and treating modules 40. The second transfer passage 34b extends from a location adjacent to the indexer 20 to a location adjacent to the interface unit 50 in the first direction 12. The treating modules 40 are arranged along the length direction of the second transfer passage 34b at both sides of the second transfer passage 34b. The second main robot 36b is installed on the second transfer passage 34b. The second main robot 36b transfers the substrates between the indexer 20, treating modules 40, and interface unit 50.

The first treating portion 32a includes modules performing a coating process. The second treating portion 32b includes modules performing a developing process. The first treating portion 32a may be disposed at the upper layer of the first treating unit 30 and the second treating portion 32b may be disposed at the lower layer of the first treating unit 30. In this case, the process flow may start at the upper layer of the first treating unit 30 and end at the lower layer of the first treating unit 30. The second treating portion 32b may be disposed at the upper layer of the first treating unit 30. In this case, the process flow may start at the lower layer of the first treating unit 30 and end at the upper layer.

Further, the first and second treating portions 32a and 32b may have all of the modules performing the coating process and the module performing the developing process. In this case, the process flow may start at the upper layer of the first treating unit 30 and end at the upper layer of the first treating unit 30. Alternatively, the process flow may start at the lower layer of the first treating unit 30 and end at the lower layer of the first treating unit 30.

The modules performing the coating process may include modules performing an adhesion process, modules performing a cooling process for the substrates, modules performing a photo-resist coating process, and modules performing a soft baking process. The modules performing the developing process may include modules for heating the exposed substrates to a predetermined temperature, modules for cooling the substrates, modules for removing exposed regions or unexposed regions by applying a developing solution on the substrates, and modules performing a hard baking process.

The interface unit 50 includes a frame 51, a first substrate receiving portion 52, and first and second interface unit robots 200a and 200b. The frame 51 is installed at the rear end portion of the first treating unit 30 such that it is symmetrical with the indexer 20 with reference to the first treating unit 30. The first interface unit robot 200a is arranged at a front end portion of an inner side of the frame 51 along a ling extending in the first direction 12. The second interface unit robot 200b is arranged at a rear end of the inside of the frame 51.

The first interface unit robot 200a includes a horizontal guide 210a, a vertical guide 220a, and a robot arm 230a. The robot arm 230a is linearly movable along the line extending in the first direction 12 and is rotatable about the Z-axis. The horizontal guide guides linear movement of the robot arm 230a in the second direction 14 and the vertical guide 220a guides the linear movement of the robot arm 230a in the third direction 16. The robot arm 230a linearly moves in the second direction 14 along the horizontal guide 210a and rotates about the Z-axis. The robot arm 230a is movable in the third direction 16.

The second interface unit robot 200b has the same structure as the first interface unit robot 200a. The reference numbers 210b, 220b, and 230b that are not described indicate a horizontal guide, a vertical guide, and a robot arm, respectively.

The first substrate receiving portion 52 is disposed at an inner-center of the frame 51. A first buffer unit 70 may be disposed at a first side of the first substrate receiving portion 52 such that it is located at a height corresponding to the first treating portion 32a. A second buffer unit 80 is disposed at a second side of the first substrate receiving portion 52 such that it is located at a height corresponding to the second treating portion 32b. For example, when the first treating portion 32a is disposed at the upper layer and the second treating portion 32b is disposed at the lower layer as shown in FIG. 2, the first buffer unit 70 is provided above the first substrate receiving portion 52 and the second buffer unit 80 is provided under the first substrate receiving portion 52. Alternatively, when the first treating portion 32a is located at the lower layer and the second treating portion 32b is located at the upper layer, the first buffer unit 70 is provided under the first substrate receiving portion 52 while the second buffer unit 80 is provided above the first substrate receiving portion 52. The first substrate receiving portion 52 and the first and second buffer units 70 and 80 have slots (not shown) through which the substrates are inserted.

A process time at the first treating unit 30 is determined by a substrate treating time required for performing the photo-resist coating, pre-baking, developing, and post-baking processes and a sending-back time in the first treating unit 30. These times can constantly remain.

A process time at the second treating unit (exposing unit) 60 is determined by a time required for photographing an exposing pattern using an exposing device, a substrate sending-back time in the second treating unit 60, and a time required for determining a position of the substrate. Among the times, the time required for photographing and the substrate sending-back time constantly remain but the time required for determining the position may vary.

When the substrate position determining time of the second treating unit 60 varies, the substrate transfer before performing the exposing process and the substrate transfer after performing the exposing process cannot be sequentially performed and thus the substrate transfer may be retarded. In order to prevent the retardation of the substrate transfer, the first and second buffer units 70 and 80 are installed in the interface unit 50.

The first buffer unit 70 provides a place where the substrates transferred from the first treating portion 32a stand by to prevent the transfer retardation and the second buffer unit 80 provides a place where the substrates that will be transferred to the second treating portion 32b stand by to prevent the transfer retardation. The first substrate receiving portion 52 receives substrates that are received in the first buffer unit 70 and will be transferred to the second treating unit 60 connected to the rear end portion of the frame 51.

The following will describe the operation of the substrate treating unit 10 structured as described above. The cassette C is located at the load port 22a of the indexer 20 by an operator or a transferring unit (not shown). The indexer robot 100 withdraws a substrate from the cassette C located at the load port 22a and hands the substrate over to the first main robot 36a of the first treating unit 32a. The first main robot 36a loads/unloads the substrate to the respective treating modules 40 while moving along the first transfer passage 34a. The modules 40 perform the photo-resist coating process, the pre-baking process, and the like. When the treating modules 40 complete the substrate treating process, the first main robot 36a unloads the substrate from the treating modules 40 and transfers the unloaded substrate to the first interface unit robot 200a.

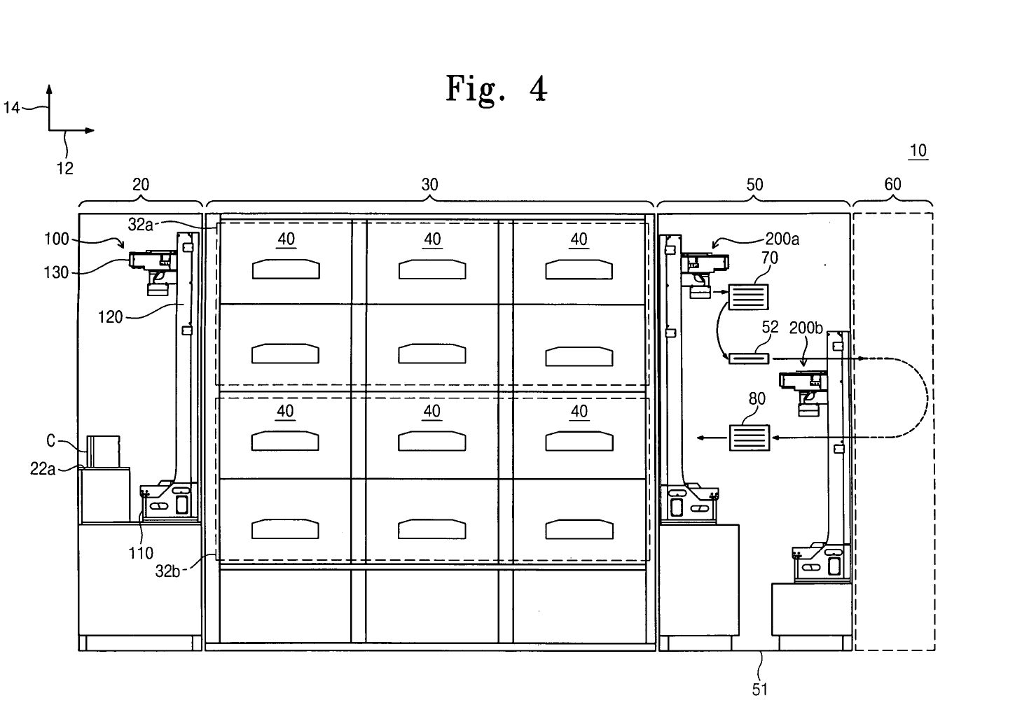

As shown in FIG. 4, the first interface unit robot 200a transfers the substrate transferred from the first main robot 36a to the first buffer unit 70. The substrates received in the first buffer unit 70 are transferred one by one to the first substrate receiving portion 52 by the first interface unit robot 200a. The substrates received in the first substrate receiving portion 52 are transferred to the second treating unit 60 by the second interface unit robot 200b. The substrates that are exposed at the second treating unit 60 are transferred to the second interface unit robot 200b and sequentially transferred to the second buffer unit 80 by the second interface unit robot 200b. The substrates received in the second buffer unit 80 are transferred one by one to the second treating unit 32b by the first interface unit robot 200a.

The first buffer unit 70 provides a place where the substrates transferred from the first treating portion 32a stand by to prevent the transfer retardation and the second buffer unit 80 provides a place where the substrates that will be transferred to the second treating portion 32b stand by to prevent the transfer retardation. The first substrate receiving portion 52 receives substrates that are received in the first buffer unit 70 and will be transferred to the second treating unit 60 connected to the rear end portion of the frame 51. The second substrate receiving portion 54 receives the substrates that are exposed and transferred from the second treating unit 60.

The substrates transferred to the second treating portion 32b are developed while being transferred to the treating modules 40 of the second treating portion 32b by the second main robot 36b. The substrates that are developed are transferred to the indexer robot 100 by the second main robot 36b and subsequently to the cassette C located on the load port 22a by the indexer robot 100.

The following will describe substrate treating apparatuses according to other embodiments of the substrate treating apparatus. Here, like reference numbers will be used to refer to same parts as those of FIG. 2 and the same parts will not be described in detail.

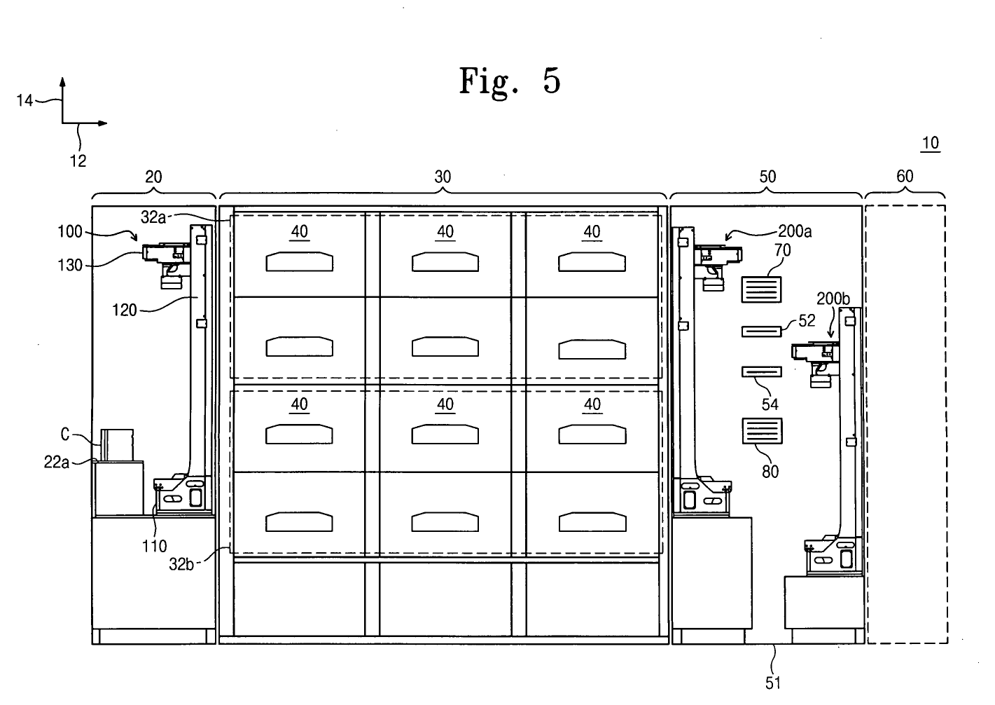

FIG. 5 is a side view of a substrate treating apparatus according to a second embodiment.

As shown in FIG. 5, first and second substrate receiving portions 52 and 54 are arranged at upper and lower portions at an inside of a frame 51. The first and second substrate receiving portions 52 and 54 may be disposed in the same arrangement as first and second treating portions 32a and 32b. For example, as shown in FIG. 5, when the first treating portion 32a is disposed at an upper layer and the second treating portion 32b is disposed at a lower layer, the first substrate receiving portion 52 is disposed above the second substrate receiving portion 54. Alternatively, when the first treating portion 32a is disposed at the lower layer and the second treating portion 32b is disposed at the upper layer, the first substrate receiving portion 52 is disposed under the second substrate receiving portion 54. A first buffer unit 70 may be provided at an opposite side of the second substrate receiving portion with reference to the first substrate receiving portion 52. A second buffer unit 80 may be provided at an opposite side of the first substrate receiving portion 52 with reference to the second substrate receiving portion 54.

For example, as shown in FIG. 5, when the first treating portion 32a is disposed at an upper layer and the second treating portion 32b is disposed at a lower layer, the first buffer unit 70 is disposed above the first substrate receiving portion 52 and the second buffer unit 80 is disposed under the second substrate receiving portion 54. Alternatively, when the first treating portion 32a is disposed at the lower layer and the second treating portion 32b is disposed at the upper layer, the first buffer unit 70 is disposed under the first substrate receiving portion 52 and the second buffer unit 80 is disposed above the second substrate receiving portion 54.

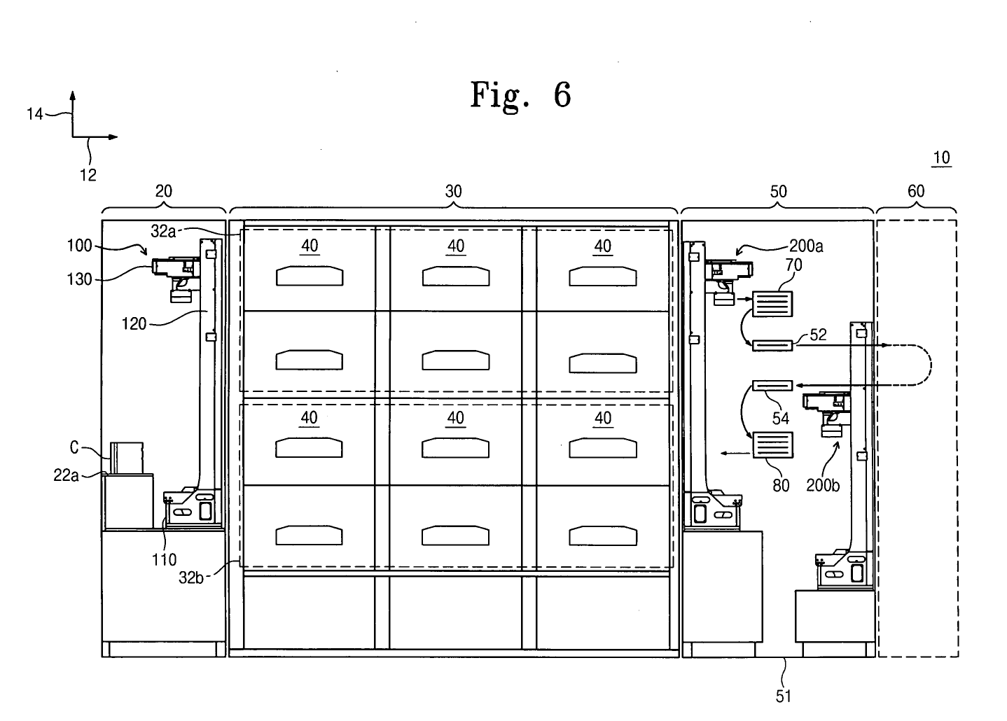

The following will describe a substrate transferring process by the above described arrangement. As shown in FIG. 6, the substrates transferred from the first treating unit 32a are sequentially transferred to the first buffer unit 70 by a first interface unit robot 200a. The substrates received in the first buffer unit 70 are transferred one by one to the first substrate receiving portion 52 by the first interface unit robot 200a. The substrates received in the first substrate receiving portion 52 are transferred to the second treating unit 60 by the second interface unit robot 200b. The substrates that are exposed at the second treating unit 60 are transferred to a second interface unit robot 200b and sequentially transferred to the second substrate receiving portion 54 by the second interface unit robot 200b. The substrates received in the second substrate receiving portion 54 are transferred to the second buffer unit 80 by the first interface unit robot 200a. The substrates received in the second buffer unit 80 are transferred one by one to the second treating unit 32b by the first interface unit robot 200a.

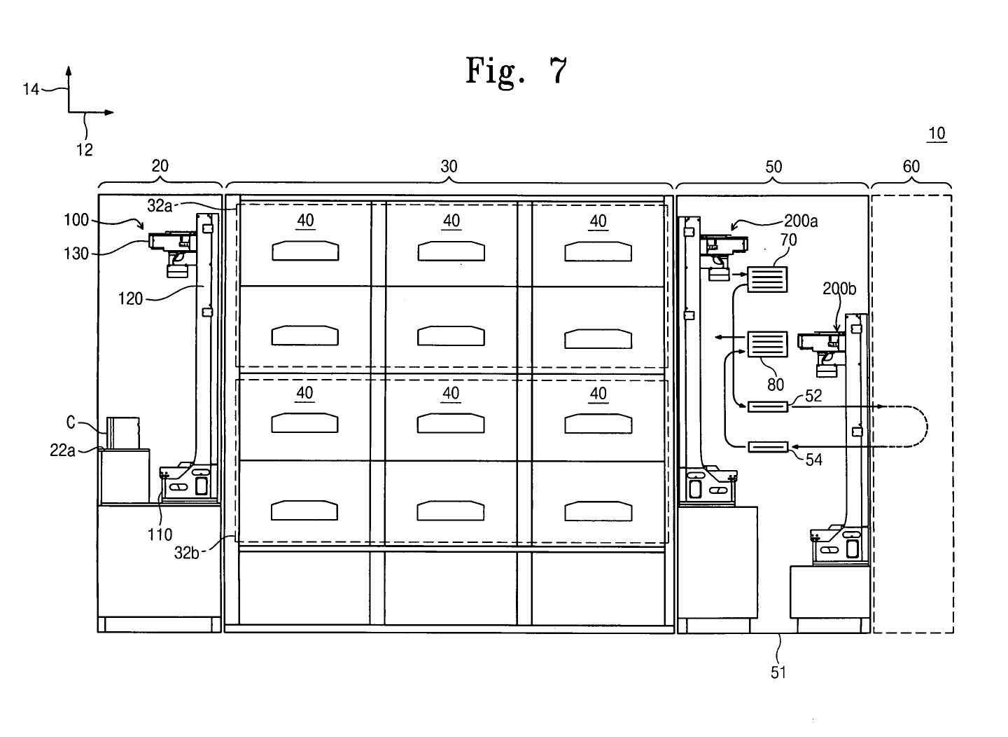

First and second substrate receiving portions 52 and 54 of substrate treating apparatuses shown in FIGS. 7 to 10 are identically arranged to those of FIG. 5, the detailed description thereof will be omitted herein.

FIG. 7 is a side view of a substrate treating apparatus according to a third embodiment of the present invention.

A first buffer unit 70 may be provided in a frame 51 such that it is disposed at an opposite side of the second substrate receiving portion with reference to the first substrate receiving portion 52. A second buffer unit 80 may be provided between the first buffer unit 70 and the first substrate receiving portion 52.

For example, as shown in FIG. 7, when the first treating portion 32a is disposed at an upper layer and the second treating portion 32b is disposed at a lower layer, the first buffer unit 70 is disposed above the first substrate receiving portion 52 and the second buffer unit 80 is disposed between the first buffer unit 70 and the first substrate receiving portion 52. Alternatively, when the first treating portion 32a is disposed at the lower layer and the second treating portion 32b is disposed at the upper layer, the first buffer unit 70 is disposed under the first substrate receiving portion 52 and the second buffer unit 80 is disposed between the first buffer unit 70 and the first substrate receiving portion 52.

The substrate transfer is performed along a substrate transfer path of FIG. 7. The substrate transfer is sequentially performed through the first treating portion 32a, the first buffer unit 70, the first substrate receiving portion 52, the second treating unit 60, the second substrate receiving portion 54, the second buffer unit 80, and the second treating portion 32b. This is same as the substrate transfer process of the substrate treating apparatus of FIG. 6. However, since the arrangement of the first and second buffer units 70 and 80 and the first and second substrate receiving portions 52 and 54 are different to that of FIG. 6, the part's movement length in the substrate transferring process is different. The part's movement length of this embodiment will be understood when referring to the above-described arrangement of the first and second buffer units 70 and 80 and the first and second substrate receiving portions 52 and 54. Therefore, the detailed description of the part's movement length of this embodiment will be omitted.

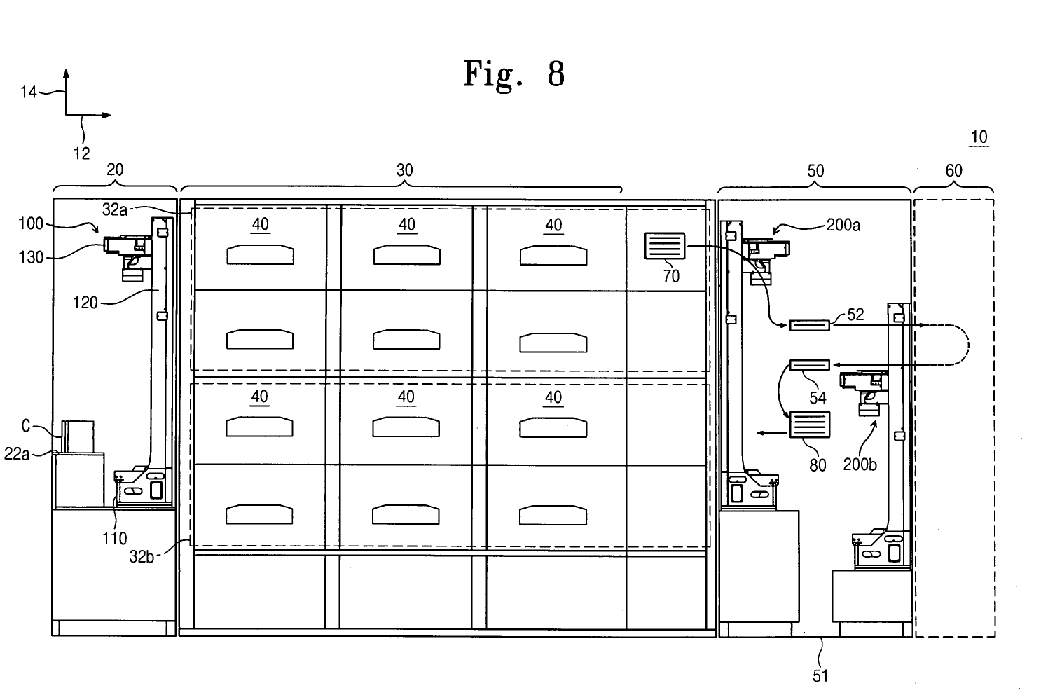

FIG. 8 is a side view of a substrate treating apparatus according to a fourth embodiment of the present invention.

Referring to FIG. 8, a first buffer unit 70 may be provided adjacent to an interface unit 50 in a first treating portion 32a. A second buffer unit 80 may be provided in a frame 51 such that it is disposed at an opposite side of the first substrate receiving portion 52 with reference to the second substrate receiving portion 54.

For example, as shown in FIG. 8, when the first treating portion 32a is disposed at an upper layer and the second treating portion 32b is disposed at a lower layer, the first buffer unit 70 may be provided at a region adjacent to the interface unit 50 in a region extending in a length direction of a first transfer passage 34a (see FIGS. 1 and 3). In addition, the first buffer unit 70 may be provided at a side of the region adjacent to the interface unit 50 in the region extending in the length direction of the first transfer passage 34a (see FIGS. 1 and 3). The second buffer unit 80 may be provided under the second substrate receiving portion 54.

Alternatively, when the first treating portion 32a is disposed at the lower layer and the second treating portion 32b is disposed at the upper layer, the first buffer unit 70 may be provided at a region adjacent to the interface unit 50 in a region extending in a length direction of a first transfer passage (not shown) arranged at the lower layer. In addition, the first buffer unit 70 may be provided at a side of the region adjacent to the interface unit 50 in the region extending in a length direction of the first transfer passage (not shown) arranged at the lower layer. The second buffer unit 80 may be provided above the second substrate receiving portion 54.

The substrate transfer is performed along a substrate transfer path of FIG. 8 and the detailed description thereof will be omitted herein with the same case of FIG. 7.

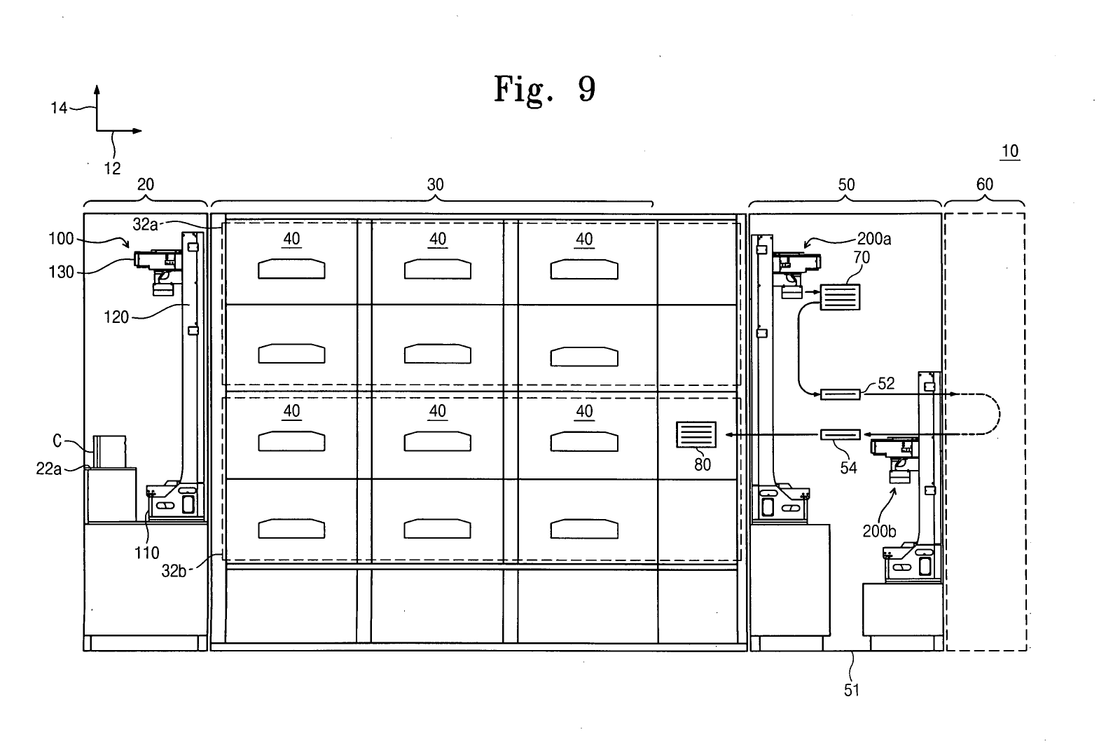

FIG. 9 is a side view of a substrate treating apparatus according to a fifth embodiment of the present invention.

Referring to FIG. 9, a first buffer unit 70 may be provided in a frame 51 such that it is disposed at an opposite side of the second substrate receiving portion 54 with reference to the first substrate receiving portion 52. A second buffer unit 80 may be provided adjacent to an interface unit 50 in a second treating portion 32b.

For example, as shown in FIG. 9, when the first treating portion 32a is disposed at an upper layer and the second treating portion 32b is disposed at a lower layer, the second buffer unit 80 may be provided at a region adjacent to the interface unit 50 in a region extending in a length direction of a second transfer passage 34b (see FIG. 3). In addition, the second buffer unit 80 may be provided at a side of the region adjacent to the interface unit 50 in the region extending in the length direction of the second transfer passage 34b (see FIG. 3). The first buffer unit 70 may be provided above the first substrate receiving portion 52.

Alternatively, when the first treating portion 32a is disposed at the lower layer and the second treating portion 32b is disposed at the upper layer, the second buffer unit 80 may be provided at a region adjacent to the interface unit 50 in a region extending in a length direction of a second transfer passage (not shown) arranged at the upper layer. In addition, the second buffer unit 80 may be provided at a side of the region adjacent to the interface unit 50 in the region extending in the length direction of the second transfer passage (not shown) arranged at the upper layer. The first buffer unit 70 may be provided under the first substrate receiving portion 54.

The substrate transfer is performed along a substrate transfer path of FIG. 9 and the detailed description thereof will be omitted herein with the same case of FIG. 7.

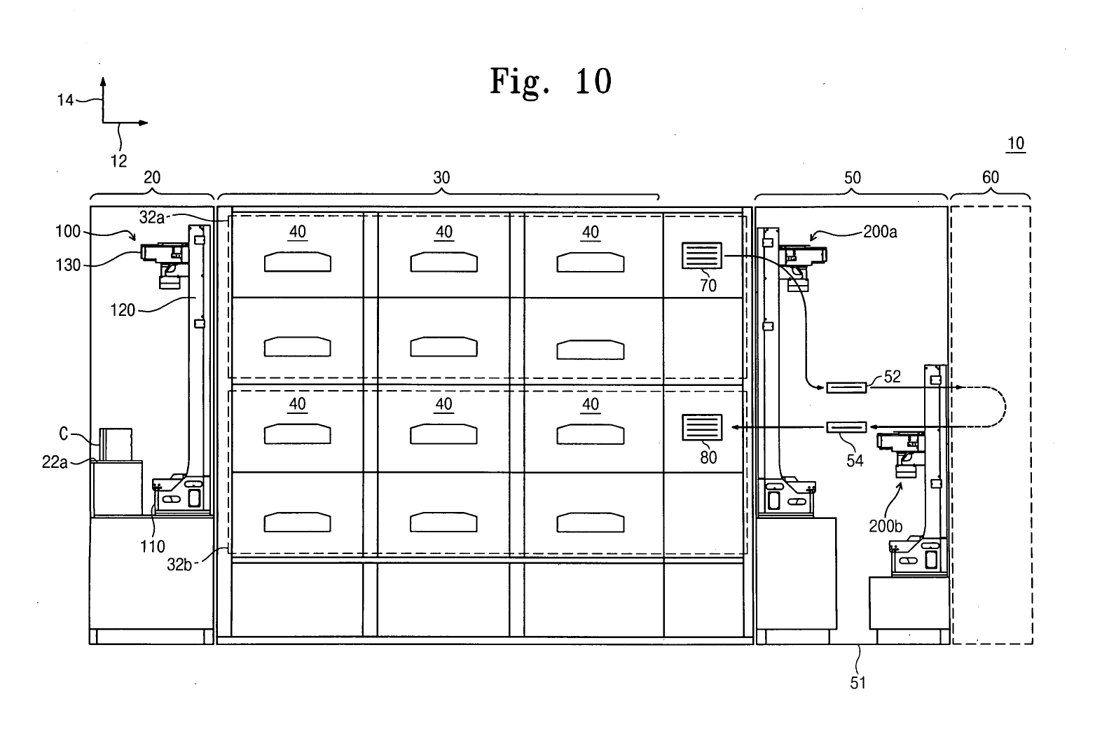

FIG. 10 is a side view of a substrate treating apparatus according to a sixth embodiment of the present invention.

Referring to FIG. 10, a first buffer unit 70 may be provided adjacent to an interface unit 50 in a first treating portion 32a. A second buffer unit 80 may be provided adjacent to an interface unit 50 in a second treating portion 32b.

For example, as shown in FIG. 10, when the first treating portion 32a is disposed at an upper layer and the second treating portion 32b is disposed at a lower layer, the first buffer unit 70 may be provided at a region adjacent to the interface unit 50 in a region extending in a length direction of a first transfer passage 34a (see FIG. 3). In addition, the first buffer unit 70 may be provided at a side of the region adjacent to the interface unit 50 in the region extending in the length direction of the first transfer passage 34a (see FIG. 3). At this point, the second buffer unit 80 may disposed at a region adjacent to the interface unit 50 in a region extending in a length direction of a second transfer passage 34b (see FIG. 3). In addition, the second buffer unit 80 may be provided at a side of the region adjacent to the interface unit 50 in the region extending in the length direction of the second transfer passage 34b (see FIG. 3).

Alternatively, when the first treating portion 32a is disposed at the lower layer and the second treating portion 32b is disposed at the upper layer, the first buffer unit 70 is provided in the first treating unit 32a disposed at the lower layer and the second buffer unit 80 may be provided in the second treating unit 32b at the upper layer. At this point, the positions of the first and second buffer units 70 and 80 are similar to the case where the first treating unit 32a is disposed at the upper layer and the second treating unit 32b is disposed at the lower layer and thus the detailed description thereof will be omitted herein.

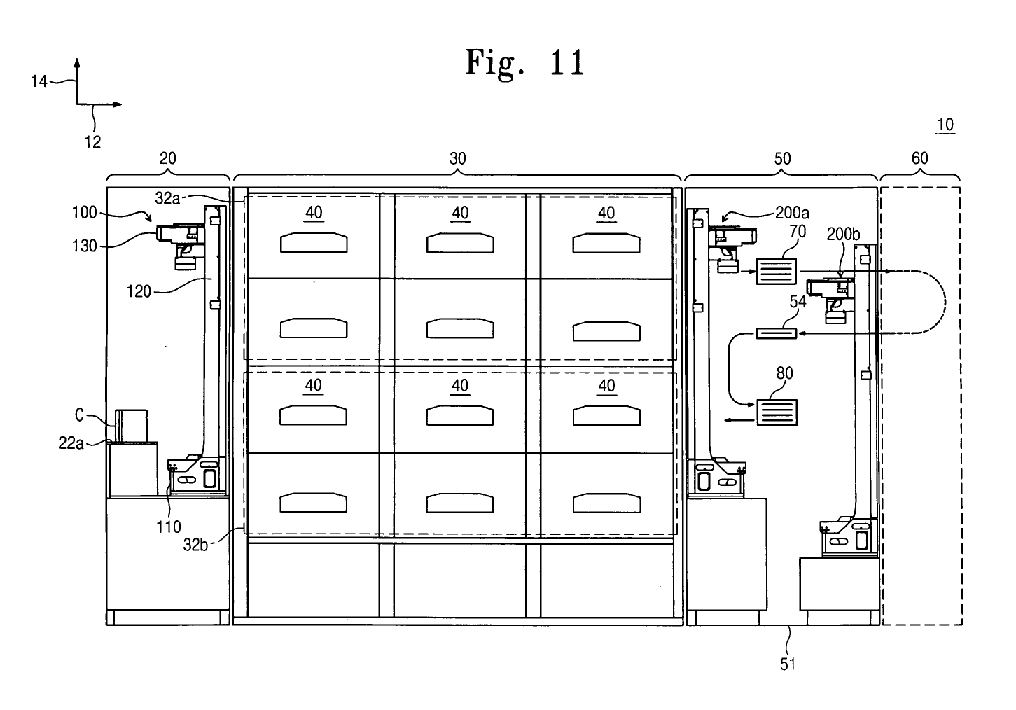

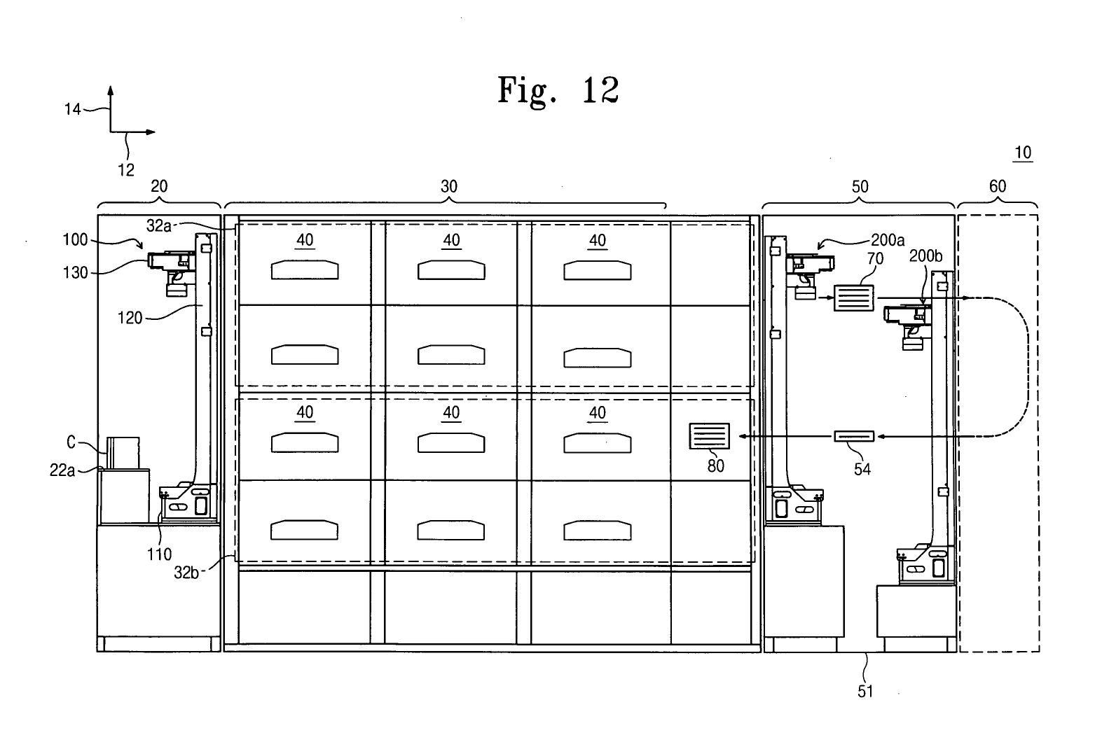

As previously described, in FIG. 2, only the first substrate receiving portion 52 is provided in the frame 51 of the interface unit 50. In FIGS. 5 to 10, both of the first and second substrate receiving portions 52 and 54 are provided in the frame 51 of the interface unit 50. Unlike the above embodiments, only the second substrate receiving portion 54 may be provided in the frame of the interface unit 50. This will be described with reference to FIGS. 11 and 12.

FIG. 11 is a side view of a substrate treating apparatus according to a seventh embodiment of the present invention.

Referring to FIG. 11, a second substrate receiving portion 54 is disposed at an inner-center of a frame 51. A first buffer unit 70 may be disposed at a first side of the second substrate receiving portion 54 such that it is located at a height corresponding to a first treating portion 32a. A second buffer unit 80 is disposed at a second side of the second substrate receiving portion 54 such that it is located at a height corresponding to the second treating portion 32b. For example, when the first treating portion 32a is disposed at the upper layer and the second treating portion 32b is disposed at the lower layer as shown in FIG. 11, the first buffer unit 70 is provided above the second substrate receiving portion 54 and the second buffer unit 80 is provided under the second substrate receiving portion 54. Alternatively, when the first treating portion 32a is located at the lower layer and the second treating portion 32b is located at the upper layer, the first buffer unit 70 is provided under the second substrate receiving portion 54 while the second buffer unit 80 is provided above the second substrate receiving portion 54. The second substrate receiving portion 54 and the first and second buffer units 70 and 80 have slots (not shown) through which the substrates are inserted.

The first buffer unit 70 provides a place where the substrates transferred from the first treating portion 32a stand by to prevent the transfer retardation and the second buffer unit 80 provides a place where the substrates that will be transferred to the second treating portion 32b stand by to prevent the transfer retardation. The second substrate receiving portion 54 receives substrates that are transferred from the second treating unit 60 connected to the rear end portion of the frame 51.

The following will describe a substrate transferring process by the above described arrangement. As shown in FIG. 11, the substrates transferred from the first treating unit 32a are sequentially transferred to the first buffer unit 70 by a first interface unit robot 200a. The substrates received in the first buffer unit 70 are transferred one by one to the second treating unit 60 by a second interface unit robot 200b. The substrates that are exposed at the second treating unit 60 are sequentially transferred to the second substrate receiving portion 54 by the second interface unit robot 200b. The substrates received in the second substrate receiving portion 54 are transferred one by one to the second buffer unit 80 and subsequently to the second treating unit 32b by the first interface unit robot 200a.

FIG. 12 is a side view of a substrate treating apparatus according to an eighth embodiment of the present invention.

Referring to FIG. 12, a first buffer unit 70 may be provided at a first side, which corresponds to a height at which a first treating unit 32a is located, of one of upper and lower portions of a second substrate receiving portion 54 in a frame 51.

For example, when the first treating portion 32a is disposed at the upper layer and the second treating portion 32b is disposed at the lower layer as shown in FIG. 12, the first buffer unit 70 is provided above the second substrate receiving portion 54 and the second buffer unit 80 is provided at a region adjacent to the interface unit 50 in a region extending in a length direction of a second transfer passage 34b (see FIG. 3). In addition, the second buffer unit 80 may be provided at a side of the region adjacent to the interface unit 50 in the region extending in the length direction of the second transfer passage 34b (see FIG. 3). The first buffer unit 70 may be provided above the second substrate receiving portion 54.

Alternatively, when the first treating portion 32a is disposed at the lower layer and the second treating portion 32b is disposed at the upper layer as shown in FIG. 11, the first buffer unit 70 is provided under the second substrate receiving portion 54 and the second buffer unit 80 is provided at a region adjacent to the interface unit 50 in a region extending in a length direction of a second transfer passage (not shown) at the upper layer. In addition, the second buffer unit 80 may be provided at a side of the region adjacent to the interface unit 50 in the region extending in the length direction of the second transfer passage (not shown).

The substrate transfer is performed along a substrate transfer path of FIG. 12. The substrate transfer is sequentially performed through the first treating portion 32a, the first buffer unit 70, the second treating unit 60, the second substrate receiving portion 54, the second buffer unit 80, and the second treating portion 32b. This is same as the substrate transfer process of the substrate treating apparatus of FIG. 11. However, since the arrangement of the first and second buffer units 70 and 80 and the first and second substrate receiving portions 52 and 54 are different to that of FIG. 11, the part's movement length in the substrate transferring process is different. The part's movement length of this embodiment will be understood when referring to the above-described arrangement of the first and second buffer units 70 and 80 and the substrate transferring order. Therefore, the detailed description of the part's movement length of this embodiment will be omitted.

According to the embodiments of the present invention, the substrates can be more effectively transferred between the treating unit for treating the substrates before and after the exposing process and the exposing unit for exposing the substrates.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate treating apparatus comprising:
a first treating unit having a dual layer structure in which a first treating portion performing a coating process and a second treating portion performing a developing process are arranged in a vertical direction;
a first buffer unit providing a place where substrates treated at the first treating portion stand by;
a second buffer unit providing a place where the substrates treated at the second treating portion stand by;
a second treating unit performing an exposing process; and
an interface unit transferring the substrates between the first and second buffer units and the second treating unit,
wherein the interface unit comprises:
a frame disposed adjacent to the first treating unit; and
a first substrate receiving portion disposed in the frame and receiving the substrates that are received in the first buffer unit and will be transferred to the second treating unit.

2. The substrate treating apparatus of claim 1, wherein the first buffer unit is provided at a first side of the first substrate receiving portion in the frame such that the first buffer unit is located at a height corresponding to the first treating portion; and
the second buffer unit is provided at a second side of the first substrate receiving portion in the frame such that the second buffer unit is located at a height corresponding to the second treating portion.

3. The substrate treating apparatus of claim 1, wherein the interface unit is disposed in the frame and further comprises a second substrate receiving portion for receiving the substrates that are transferred from the second treating unit and exposed.

4. The substrate treating apparatus of claim 3, wherein the first and second substrate receiving portions are arranged in a same order as the first and second treating portions that are arranged in the vertical direction.

5. The substrate treating apparatus of claim 4, wherein the first buffer unit is provided in the frame such that the first buffer unit is disposed at an opposite side of the second substrate receiving portion with reference to the first substrate receiving portion; and
the second buffer unit is provided in the frame such that the second buffer unit is disposed at an opposite side of the first substrate receiving portion with reference to the second substrate receiving portion.

6. The substrate treating apparatus of claim 4, wherein the first buffer unit is provided in the frame such that the first buffer unit is disposed at an opposite side of the second substrate receiving portion with reference to the first substrate receiving portion; and
the second buffer unit is provided between the first buffer unit and the first substrate receiving portion.

7. The substrate treating apparatus of claim 4, wherein the first buffer unit is provided adjacent to the interface unit in the first treating portion; and
the second buffer unit is provided in the frame such that the second buffer unit is disposed at an opposite side of the first substrate receiving portion with reference to the second substrate receiving portion.

8. The substrate treating apparatus of claim 4, wherein the first buffer unit is provided in the frame such that the first buffer unit is disposed at an opposite side of the second substrate receiving portion with reference to the first substrate receiving portion; and
the second buffer unit is provided adjacent to the interface unit in the second treating portion.

9. The substrate treating apparatus of claim 4, wherein the first buffer unit is provided adjacent to the interface unit in the first treating portion; and
the second buffer unit is provided adjacent to the interface unit in the second treating portion.

10. A substrate treating apparatus comprising:
a first treating unit having a dual layer structure in which a first treating portion performing a coating process and a second treating portion performing a developing process are arranged in a vertical direction;
a first buffer unit providing a place where substrates treated at the first treating portion stand by;
a second buffer unit providing a place where the substrates treated at the second treating portion stand by;
a second treating unit performing an exposing process;
an interface unit transferring the substrates between the first and second buffer units and the second treating unit,
wherein the interface unit comprises:
a frame disposed adjacent to the first treating unit; and
a second substrate receiving portion disposed in the frame and receiving the substrates that are exposed and transferred from the second treating unit.

11. The substrate treating apparatus of claim 10, wherein the first buffer unit is provided at a first side of the second substrate receiving portion in the frame such that the first buffer unit is located at a height corresponding to the first treating portion; and
the second buffer unit is provided at a second side of the second substrate receiving portion in the frame such that the second buffer unit is located at a height corresponding to the second treating portion.

12. The substrate treating apparatus of claim 10, wherein the first buffer unit is provided at a first side, which corresponds to a height at which the first treating portion is located, of one of upper and lower portions of the second substrate receiving portion in the frame; and
the second buffer unit may be provided adjacent to the interface unit in the second treating portion.

13. A method for transferring between first and second treating units using the substrate treating apparatus of claim 1, the method comprising:
transferring the substrates treated in the first treating portion to the first buffer unit;
transferring the substrates from the first buffer unit to the first substrate receiving portion;
transferring the substrates from the first substrate receiving portion to the second treating unit;
transferring the substrates that are exposed at the second treating unit to the second buffer unit; and
transferring the substrates from the second buffer unit to the second treating portion.

14. The method of claim 13, wherein the substrates treated at the first treating portion are transferred to the first substrate receiving portion via the first buffer unit that is provided at a first side of the first substrate receiving portion in the frame such that the first buffer unit is located at a height corresponding to the first treating portion; and
the substrates that are exposed at the second treating unit are transferred to the second treating portion via the second buffer unit that is provided at a second side of the first substrate receiving portion in the frame such that the second buffer unit is located at a height corresponding to the second treating portion

15. A method for transferring between first and second treating units using the substrate treating apparatus of claim 3, the method comprising:
transferring the substrates treated in the first treating portion to the first buffer unit;
transferring the substrates from the first buffer unit to the first substrate receiving portion;
transferring the substrates from the first substrate receiving portion to the second treating unit;
transferring the substrates that are exposed at the second treating unit to the second substrate receiving portion;
transferring the substrates from the second substrate receiving portion to the second buffer unit; and
transferring the substrates from the second buffer unit to the second treating portion.

16. The method of claim 15, wherein the first and second substrate receiving portions are arranged in a same order as the first and second treating portions that are arranged in the vertical direction.

17. The method of claim 16, wherein the substrates treated at the first treating portion are transferred to the first substrate receiving portion via the first buffer unit that is disposed at an opposite side of the second substrate receiving portion with reference to the first substrate receiving portion; and
the substrates that are exposed and receiving in the second substrate receiving portion are transferred to the second treating portion via the second buffer unit that is disposed at an opposite side of the first substrate receiving portion with reference to the second substrate receiving portion.

18. The method of claim 16, wherein the substrates treated at the first treating portion are transferred to the first substrate receiving portion via the first buffer unit that is provided in the frame such that the first buffer unit is disposed at an opposite side of the second substrate receiving portion with reference to the first substrate receiving portion; and
the substrates that are exposed and receiving in the second substrate receiving portion are transferred to the second treating portion via the second buffer unit that is provided in the frame such that the second buffer unit is disposed between the first buffer unit and the first substrate receiving portion.

19. The method of claim 16, wherein the substrates treated at the first treating portion are transferred to the first substrate receiving portion via the first buffer unit that is provided adjacent to the interface unit in the first treating portion; and
the substrates that are exposed and receiving in the second substrate receiving portion are transferred to the second treating portion via the second buffer unit that is provided in the frame such that the second buffer unit is disposed at an opposite side of the first substrate receiving portion with reference to the second substrate receiving portion.

20. The method of claim 16, wherein the substrates treated at the first treating portion are transferred to the first substrate receiving portion via the first buffer unit that is provided in the frame such that the first buffer unit is disposed at an opposite side of the second substrate receiving portion with reference to the first substrate receiving portion; and
the substrates that are exposed and receiving in the second substrate receiving portion are transferred to the second treating portion via the second buffer unit that is provided adjacent to the interface unit in the second treating portion.

21. The method of claim 16, wherein the substrates treated at the first treating portion are transferred to the first substrate receiving portion via the first buffer unit that is provided adjacent to the interface unit in the first treating portion; and
the substrates that are exposed and receiving in the second substrate receiving portion are transferred to the second treating portion via the second buffer unit that is provided adjacent to the interface unit in the second treating portion.

22. A method for transferring between first and second treating units using the substrate treating apparatus of claim 10, the method comprising:
transferring the substrates treated in the first treating portion to the first buffer unit;
transferring the substrates from the first buffer unit to the second treating unit;
transferring the substrates that are exposed at the second treating unit to the second substrate receiving portion;
transferring the substrates from the second substrate receiving portion to the second buffer unit; and
transferring the substrates from the second buffer unit to the second treating portion.

23. The method of claim 22, wherein the substrates treated at the first treating portion are transferred to the second treating unit via the first buffer unit that is provided at a first side of the second substrate receiving portion in the frame such that the first buffer unit is located at a height corresponding to the first treating portion;
the substrates that are exposed at the second treating unit are transferred to the second substrate receiving portion between the first and second buffer units; and
the substrates received in the second substrate receiving portion are transferred to the second treating portion via the second buffer unit that is provided at a second side of the second substrate receiving portion in the frame such that the second buffer unit is located at a height corresponding to the second treating portion.

24. The method of claim 22, wherein the substrates treated at the first treating portion are transferred to the second treating unit via the first buffer unit that is provided at a first side, which corresponds to a height at which the first treating portion is located, of one of upper and lower portions of the second substrate receiving portion in the frame;
the substrates that are exposed at the second treating unit are transferred to the second substrate receiving portion; and
the substrates received in the second substrate receiving portion are transferred to the second treating portion via the second buffer unit that is provided adjacent to the interface unit in the second treating portion.
